(19) United States
(12) Patent Application Publication
(10) Pub. No.: US 2014/0084329 A1
(43) Pub. Date: Mar. 27, 2014

(54) LIGHT EMITTING UNIT, LIGHT EMITTING DEVICE, AND METHOD OF MANUFACTURING LIGHT EMITTING UNIT

(71) Applicant: ROHM CO., LTD., Kyoto (JP)

(72) Inventor: Tomoharu HORIO, Kyoto (JP)

(73) Assignee: ROHM CO., LTD., Kyoto (JP)

(21) Appl. No.: 14/036,584

(22) Filed: Sep. 25, 2013

(30) Foreign Application Priority Data
Sep. 26, 2012 (JP) 2012-211612

(51) Int. Cl. H01L 33/62

(52) U.S. Cl. CPC H01L 33/62
USPC 257/99; 438/22

(57) ABSTRACT

A light emitting unit includes: a light emitting element; a first lead having a first principal surface on which the light emitting element is disposed, a first rear surface configured to face opposite the first principal surface, and a first side configured to connect the first principal surface and the first rear surface; a second lead having a second side configured to face the first side; and a first resin molding body configured to hold the first lead and the second lead. The first resin molding body covers the first principal surface to expose a region of the first principal surface where the light emitting element is disposed, and at least a portion of the first side is exposed from the first resin molding body.

### CROSS-REFERENCE TO RELATED APPLICATION

This application is based upon and claims the benefit of priority from Japanese Patent Application No. 2012-211612, filed on Sep. 26, 2012, the entire contents of which are incorporated herein by reference.

### TECHNICAL FIELD

The present disclosure relates to a light emitting unit, a light emitting device containing the light emitting unit, and a method of manufacturing the light emitting unit.

### BACKGROUND

There have been conventionally known surface mounting type light emitting units. A conventional light emitting unit includes first and second leads made of metal, a light emitting element mounted on the first lead, a first resin molding body fixing the first and second leads, and a second resin molding body covering the light emitting element. The first resin molding body has a concave portion to accommodate the light emitting element and the second resin molding body. Such a concave portion is difficult to be formed by injection molding. Therefore, the first resin molding body is formed by performing a transfer molding method using a thermosetting resin.

The light emitting unit is used after being assembled as a light source into a light emitting device. The light emitting device includes a mounting substrate on which a wiring pattern connected to a power supply is formed and the light emitting unit is mounted on the mounting substrate. When mounting the light emitting unit on the mounting substrate, the first and second leads are connected to the wiring pattern by means of soldering. In order to improve the reliability of the light emitting device, there is a need to improve connection strength between the wiring pattern and the first and second leads.

### SUMMARY

The present disclosure provides some embodiments of a light emitting unit, which is capable of being firmly connected to a mounting substrate, a light emitting device containing the light emitting unit, and a method of manufacturing the light emitting unit.

According to one embodiment of the present disclosure, there is provided a light emitting unit including: a light emitting element; a first lead having a first principal surface on which the light emitting element is disposed, a first rear surface configured to face opposite the first principal surface, and a first side configured to connect the first principal surface and the first rear surface; a second lead having a second side configured to face the first side; and a first resin molding body configured to hold the first lead and the second lead. The first resin molding body covers the first principal surface to expose a region of the first principal surface where the light emitting element is disposed, and at least a portion of the first side is exposed from the first resin molding body.

With this configuration, since a portion of the first side is exposed from the first resin molding body, when the light emitting unit is connected to a mounting substrate by means of, for example, a solder, it is possible to increase a contact area between the first lead and the solder. This can preferably provide a strong connection between the first lead and the mounting substrate.

The second lead may have a second principal surface configured to face in the same direction as the first principal surface and a second rear surface configured to face in the same direction as the first rear surface, wherein the first resin molding body covers the second principal surface to expose a portion of the second principal surface, and at least a portion of the second side is exposed from the first resin molding body.

The first rear surface and the second rear surface may be exposed from the first resin molding body.

The first resin molding body may have a band-shaped portion configured to contact the first side and the second side.

The light emitting unit may further include a concave portion between the first side and the second side, wherein the band-shaped portion faces the concave portion.

The light emitting unit may further include a second resin molding body configured to cover the light emitting element, wherein the first resin molding body has a window portion formed to accommodate the second resin molding body.

The second resin molding body may contact the first principal surface and the second principal surface, and the band-shaped portion may contact the second resin molding body.

According to another embodiment of the present disclosure, there is provided a light emitting device including: the above-described light emitting unit; a first wiring pattern connected to the first lead; and a first joining member configured to connect the first wiring pattern and the first rear surface.

The first joining member may contact the first side.

The light emitting device may further include: a second wiring pattern connected to the second lead; and a second joining member configured to connect the second wiring pattern and the second rear surface.

The second joining member may contact the second side.

According to still another embodiment of the present disclosure, there is provided a method of manufacturing a light emitting unit, including: forming a first lead having a first principal surface, a first rear surface configured to face opposite the first principal surface, and a first side configured to connect the first principal surface and the first rear surface; forming a second lead having a second side configured to face the first side; and covering the first lead and the second lead with first resin material. Covering the first lead and the second lead with the first resin material includes exposing at least a portion of the first side from the first resin material.

Covering the first lead and the second lead with the first resin material may include: interposing a resin film between a pair of upper and lower molds; interposing the first lead and the second lead between the pair of upper and lower molds such that the first rear surface contacts the resin film; and pouring the first resin material between the pair of upper and lower molds on which the resin film, the first lead and the second lead are disposed.

The second lead may have a second rear surface configured to face in the same direction as the first rear surface, and interposing the first lead and the second lead between the pair of upper and lower molds includes contacting the second rear surface with the resin film.

Interposing the first lead and the second lead between the pair of upper and lower molds may include putting a portion of the resin film between the first side and the second side.

The pair of upper and lower molds may include a lower mold having a flat bottom surface and an upper mold having a convex portion configured to project toward the bottom surface, and the resin film may be disposed on the bottom surface.

The method may further include contacting the convex portion with the first principal surface.

The second lead may have a second principal surface configured to face in the same direction as the first principal surface, and contacting the convex portion with the first principal surface may include contacting the convex portion with the second principal surface.

Covering the first lead and the second lead with first resin material may include forming a first resin molding body having a window portion corresponding to the convex portion.

The method may further include: disposing a light emitting element in the window portion; and covering the light emitting element with second resin material, wherein the covering the light emitting element with second resin material includes forming a second resin molding body covering the light emitting element.

Covering the first lead and the second lead with the first resin material may include: interposing paraffin between the first side and the second side; and heating the paraffin after covering the first lead and the second lead with the first resin material.

Interposing the paraffin may include covering a portion of the first side near the first rear surface with the paraffin and exposing a portion of the first side near the first principal surface from the paraffin.

The second lead may have a second principal surface configured to face in the same direction as the first principal surface and a second rear surface configured to face in the same direction as the first rear surface, and interposing the paraffin may include covering a portion of the second side near the second rear surface with the paraffin and exposing a portion of the second side near the second principal surface from the paraffin.

Other features and advantages of the present disclosure will be apparent from the following detailed description in conjunction with the accompanying drawings.

### BRIEF DESCRIPTION OF THE DRAWINGS

FIG. 1 is a plan view showing main parts of a light emitting unit according to an embodiment of the present invention.

FIG. 2 is a bottom view of the light emitting unit shown in FIG. 1.

FIG. 3 is a sectional view taken along line of FIG. 1.

FIG. 4 is a main part enlarged sectional view of FIG. 3.

FIG. 5 is a main part sectional view of a light emitting device containing the light emitting unit shown in FIG. 1.

FIG. 6 is a main part enlarged sectional view of FIG. 5.

FIG. 7 is a view showing a lead frame manufactured in a process of manufacturing the light emitting unit shown in FIG. 1.

FIG. 8 is a view showing upper and lower molds and a resin film used in the process of manufacturing the light emitting unit shown in FIG. 1.

FIG. 9 is a view showing a process of disposing a lead frame on the lower mold.

FIG. 10 is a sectional view taken along line X-X of FIG. 9.

FIG. 11 is a view showing a process of interposing a lead frame between the upper and lower molds.

FIG. 12 is a view showing a process of pouring resin material between the upper and lower molds.

FIG. 13 is a view showing a process after the process shown in FIG. 12.

FIG. 14 is a view showing a state after a light emitting element is disposed on the lead frame.

FIG. 15 is a view illustrating a lead frame used in another method of manufacturing the light emitting unit shown in FIG. 1.

FIG. 16 is a view showing a state where the lead frame shown in FIG. 15 is interposed between molds.

FIG. 17 is a view showing a state where resin material is poured between the molds shown in FIG. 16.

FIG. 18 is a view showing a state after the resin material shown in FIG. 17 is cured.

### DETAILED DESCRIPTION

Various embodiments of the present disclosure will now be described in detail with reference to the drawings.

Throughout the drawings, the same or similar elements, members and processes are denoted by the same reference numerals and explanations of which will not be repeated. The disclosed embodiments are provided for the purpose of illustration, not limitation, of the present disclosure.

In the specification, the phrase “connection of a member A and a member B” is intended to include direct physical connection of member A and member B as well as indirect connection thereof via other members as long as the other members have no substantial effect on the electrical connection of member A and member B or has no damage to functions and effects shown by a combination of member A and member B. Similarly, the phrase “interposition of a member C between a member A and a member B” is intended to include direct connection of member A and member C or direct connection of member B and member C as well as indirect connections thereof via other members as long as the other members have no substantial effect on the electrical connection of member A, member B and member C or has no damage to functions and effects shown by a combination of member A, member B and member C.

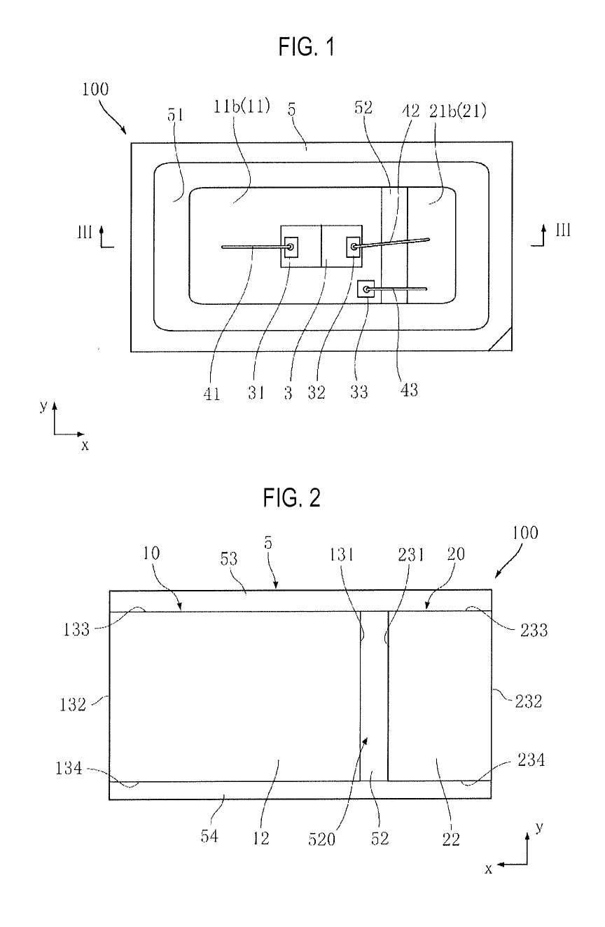

FIGS. 1 to 4 show a light emitting unit 100 according to an embodiment of the present disclosure. The light emitting unit 100 includes a first lead 10, a second lead 20, a light emitting element 3, a zener diode 33, a first wire 41, a second wire 42, a third wire 43, a first resin molding body 5 and a second resin molding body 6. For ease of understanding, the second resin molding body 6 is not shown in FIG. 1. As shown in FIG. 1, the light emitting unit 100 has a rectangular shape when viewed from the top. In the following description, it is assumed that an x direction is a longitudinal direction of the light emitting unit 100, a y direction is a width direction thereof, and a z direction is a direction orthogonal to the x and y directions. The light emitting unit 100 may, for example, be used as a part of a light emitting device (to be described later) assembled into a lighting apparatus (not shown).

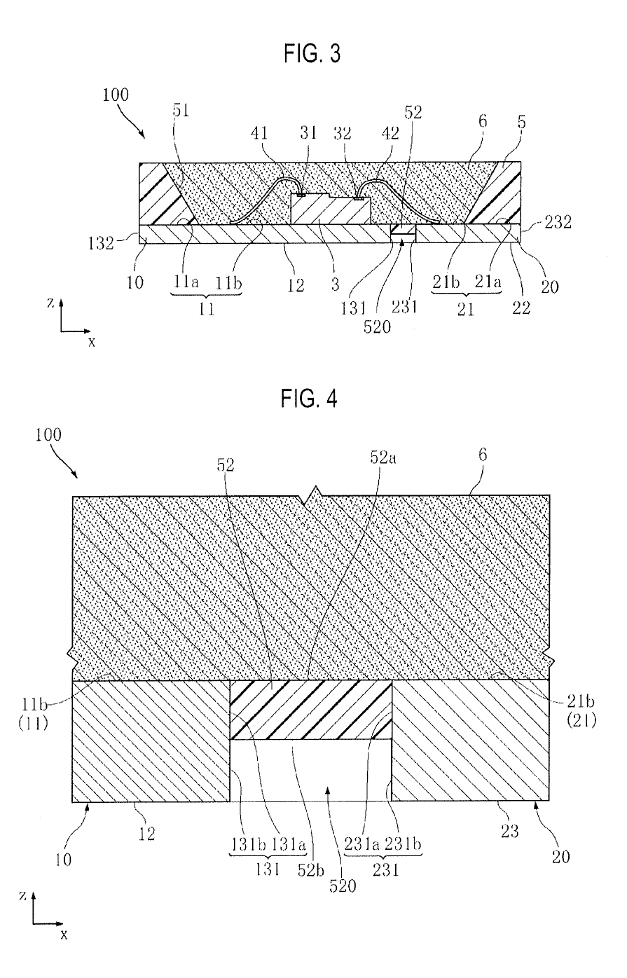

As shown in FIGS. 1 and 2, the first resin molding body 5 defines an outer shape of the light emitting unit 100. The first resin molding body 5 holds the first lead 10 and the second lead 20. As shown in FIGS. 1 and 3, a window portion 51 is formed in a central portion of the first resin molding body 5 when viewed from the top. The window portion 51 exposes a portion of the first lead 10 and a portion of the second lead 20. The light emitting element 3, the zener diode 33, the first wire 41, the second wire 42, the third wire 43 and the second resin molding body are housed in the window portion 51.

The first lead 10 is made of, for example, copper or iron and has an elongated plate shape extending in the x direction. The thickness of the first lead 10 in the z direction may be appropriately set within a range of, for example, 0.1 to 0.5 mm. In this embodiment, the thickness of the first lead 10 is set to 0.25 mm. The first lead 10 has a first principal surface 11 and a first rear surface 12 facing opposite each other in the z direction. As shown in FIG. 3, the first principal surface 11 faces upward in the z direction and the first rear surface 12 faces downward in the same direction. The first lead 10 further has a first side 131 connecting the first principal surface 11 and the first rear surface 12. The first side 131 faces the right side of FIG. 3. In addition, as shown in FIG. 3, the first lead 10 has a side 132 opposite the first side 131. As shown in FIG. 2, the first lead 10 has a side 133 and a side 134, which are orthogonal to the first side 131 and the side 132. The side 133 and the side 134 face opposite each other.

As shown in FIG. 3, the first principal surface 11 has a covered portion 11a covered with the first resin molding body 5, and an exposed portion 11b exposed from the first resin molding body 5. The first rear surface 12 and the side 132 are exposed from the first resin molding body 5. The side 133 and the side 134 are covered with the first resin molding body 5. In this embodiment, the side 132 is flush with a left end surface of the first resin molding body 5 in the x direction in FIG. 3 and the first rear surface 12 is flush with a bottom surface of the first resin molding body 5 in the z direction in FIG. 3. The side 133 and the side 134 are in contact with the first resin molding body 5 and the first lead 10 is held by the first resin molding body 5 through the side 133 and the side 134.

Only a portion of the first side 131 is covered with the first resin molding body 5 and the rest is exposed from the first resin molding body 5. FIG. 4 shows an enlargement of the neighboring portions of the first side 131. As shown in FIG. 4, the first side 131 has a covered portion 131a covered with the first resin molding body 5, and an exposed portion 131b exposed from the first resin molding body 5. The covered portion 131a is an area near the first principal surface 11 in the z direction and the exposed portion 131b is an area near the first rear surface 12 in the z direction.

The second lead 20 is made of, for example, copper or iron and has a rectangular shape having the same width as the first lead 10 in the y direction. The length of the second lead 20 in the x direction is smaller than that of the first lead 10. The thickness of the second lead 20 in the z direction is equal to that of the first lead 10. As shown in FIG. 2, the second lead 20 is arranged to be spaced apart from the first lead 10 in the x direction.

The second lead 20 has a second principal surface 21 and a second rear surface 22 facing opposite each other in the z direction. As shown in FIG. 3, the second principal surface 21 faces upward in the z direction and the second rear surface 22 faces downward in the same direction. The second lead 20 further has a second side 231 connecting the second principal surface 21 and the second rear surface 22. The second side 231 faces the left side of FIG. 3. In addition, as shown in FIG. 3, the second lead 20 has a side 232 opposite the second side 231. As shown in FIG. 2, the second lead 20 has a side 233 and a side 234 which are orthogonal to the second side 231 and the side 232. The side 233 and the side 234 face opposite each other.

As shown in FIG. 3, the second principal surface 21 has a covered portion 21a covered with the first resin molding body 5, and an exposed portion 21b exposed from the first resin molding body 5. The second rear surface 22 and the side 232 are exposed from the first resin molding body 5. The side 233 and the side 234 are covered with the first resin molding body 5. In this embodiment, the side 232 is flush with a right end surface of the first resin molding body 5 in the x direction in FIG. 3 and the second rear surface 22 is flush with the bottom surface of the first resin molding body 5 in the z direction in FIG. 3. The side 233 and the side 234 are in contact with the first resin molding body 5 and the second lead 20 is held by the first resin molding body 5 through the side 233 and the side 234.

Only a portion of the second side 231 is covered with the first resin molding body 5 and the rest is exposed from the first resin molding body 5. FIG. 4 shows an enlargement of the neighboring portions of the second side 231. As shown in FIG. 4, the second side 231 has a covered portion 231a covered with the first resin molding body 5, and an exposed portion 231b exposed from the first resin molding body 5. The covered portion 231a is an area near the second principal surface 21 in the z direction and the exposed portion 231b is an area near the second rear surface 22 in the z direction.

A distance between the first side 131 and the second side 231 may be substantial as long as the thickness of the first and second leads 10 and 20. This distance may be appropriately set within a range of, for example, 0.1 to 0.5 mm. In this embodiment, the distance between the first side 131 and the second side 231 is set to 0.25 mm.

As shown in FIG. 4, a portion (a band-shaped portion 52 which will be described later) of the first resin molding body 5 is interposed between the covered portion 131a of the first side 131 and the covered portion 231a of the second side 132. A concave portion 520 is formed between the exposed portion 131b of the first side 131 and the exposed portion 231b of the second side 231. In FIGS. 3 and 4, for convenience of understanding, the concave portion 520 is exaggerated. The dimension of the concave portion 520 in the z direction is, for example, about 20 to 100 μm.

The light emitting element 3 is a light emitting diode (LED) having a structure including, for example, an n type semiconductor layer made of GaN, an active layer and a p type semiconductor layer which are stacked in this order, and emits blue light, for example. The light emitting element 3 has a substantially parallelepiped shape and includes a first electrode terminal 31 and a second electrode terminal 32 which are arranged in the upper side of FIG. 3 in the z direction. In the example shown in FIG. 3, the second electrode terminal 32 is spaced apart from the first electrode terminal 31 and is located in the right side of the first electrode terminal 131 in the x direction in FIG. 3. The light emitting element 3 is fixed to the exposed portion 11b of the first principal surface 11 by means of, for example, a bonding material (not shown) such as a paste or the like.

The first electrode terminal 31 makes electrical conduction with the first lead 10 via the first wire 41 and the second electrode terminal 32 makes electrical conduction with the second lead 20 via the second wire 42. With this structure, when the rear surface 12 of the first lead 10 and the rear surface 22 of the second lead 20 are mounted on a mounting substrate of a light emitting device, which will be further described later, power is supplied to the first and second electrode terminals 31 and 32 to allow the light emitting element 3 to emit light.

The zener diode 33 is used to prevent an excessive reverse voltage from being applied to the light emitting element 3 and is disposed on the exposed portion 11b of the first principal surface 11, as shown in FIG. 1. The zener diode 33 is connected to the second lead 20 via the third wire 43.

The first to third wires 41, 42 and 43 are, for example, gold lines or silver lines. The first wire 41 has one end connected to the first electrode terminal 31 and the other end connected to the exposed portion 11b of the first principal surface 11. The second wire 42 has one end connected to the second electrode terminal 32 and the other end connected to the exposed portion 21b of the second principal surface 21. The third wire 43 has one end connected to the zener diode 33 and the other end connected to the exposed portion 21b of the second principal surface 21.

The first resin molding body 5 is made of, for example, white thermosetting resin. Specifically, the white thermosetting resin forming the first resin molding body 5 is obtained by adding a titanium oxide pigment in the thermosetting resin. An example of the thermosetting resin may be one selected from a group including epoxy resin, modified epoxy resin, silicone resin, modified silicone resin, acrylate resin and urethane resin. In addition to the titanium oxide, alumina or silica may be used as an additive for coloring the thermosetting resin in white.

As shown in FIGS. 1 and 3, the window portion 51 is formed in the first resin molding body 5. The window portion 51 has substantially a rectangular shape with the x direction as its longitudinal direction when viewed in the z direction and is formed in a central portion of the first resin molding body 5. The window portion 51 is configured by four inclined planes surrounding the light emitting element 3. Two of the four inclined planes are shown in FIG. 3. Both of the two inclined planes shown in FIG. 3 are formed to be closer to the light emitting element 3 in the x direction as they becomes closer to the first lead 10 in the z direction. The inclined planes of the window portion 51 reflect light emitted laterally (for example, in the x and y directions) from the light emitting element 3 toward the outside of the first resin molding body 5 (for example, toward the upper side of FIG. 3 in the z direction), which contributes to an increase in the amount of light of the light-emitting element 3.

As shown in FIG. 2, the first resin molding body 5 has a band-shaped portion 52 interposed between the first side 131 and the second side 231. As shown in FIG. 2, the band-shaped portion 52 has a certain width in the x direction and is formed to extend in the y direction. In addition, the first resin molding body 5 has a pair of holding portions 53 and 54 with the first and second leads 10 and 20 interposed therebetween and spaced from each other in the y direction. The holding portion 53 is a portion contacting the side 133 and the side 233, and the holding portion 54 is a portion contacting the side 134 and the side 234. The upper end of the band-shaped portion 52 in FIG. 2 is connected to the holding portion 53 and its lower end in FIG. 2 is connected to the holding portion 54.

As shown in FIGS. 3 and 4, the band-shaped portion 52 is formed such that its thickness in the z direction becomes smaller than those of the first and second leads 10 and 20. In addition, in this embodiment, the top surface 52a of the band-shaped portion 52 in FIG. 4 is flush with the first and second principal surfaces 11 and 21. The bottom surface 52b of the band-shaped portion 52 faces the concave portion 520.

The second resin molding body 6 is made of material transmitting light from the light emitting element 3 and is formed to cover the light emitting element 3. In this embodiment, as shown in FIG. 3, the second resin molding body 6 is filled in the inner space of the window portion 51 and also covers the first wire 41, the second wire 42, the third wire 43, the exposed portion 11b of the first principal surface 11, the exposed portion 2I b of the second principal surface 21, and the top surface 52a of the band-shaped portion 52. As shown in FIG. 4, the second resin molding body 6 makes direct contact with the exposed portion 11b of the first principal surface 11, the exposed portion 21b of the second principal surface 21, and the top surface 52a of the band-shaped portion 52.

In more detail, the second resin molding body 6 is made of, for example, a mixture of transparent epoxy resin and fluorescent material. The fluorescent material emits yellow light, for example by being excited by blue light from the light emitting element 3. When the yellow light from the fluorescent material is mixed with the blue light from the light emitting element 3, white light is emitted from the light emitting unit 100. In addition, the above-mentioned fluorescent material may be replaced with a combination of fluorescent material emitting red light by being excited by a blue light and another fluorescent material emitting green light by being excited by a blue light.

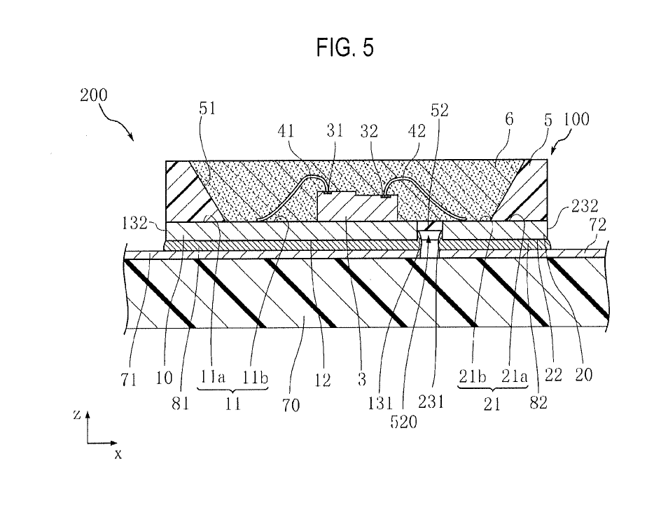

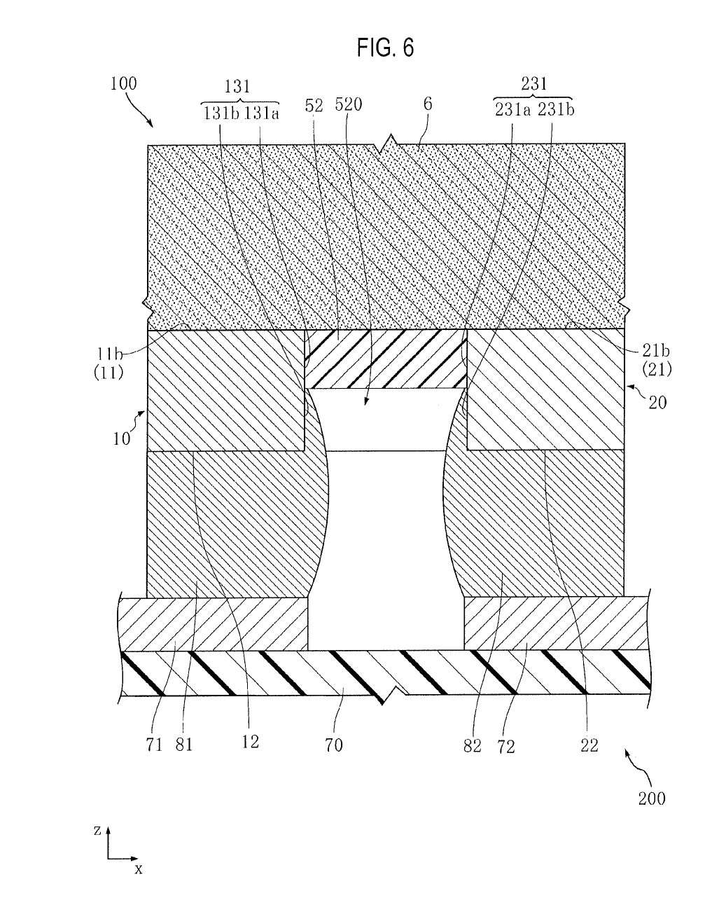

FIGS. 5 and 6 are views illustrating a light emitting device 200 incorporating the light emitting unit 100. The light emitting device 200 serves as, for example, a lighting apparatus.

The light emitting device 200 includes the light emitting unit 100, a mounting substrate 70, first and second wiring patterns 71 and 72 formed on the mounting substrate 70, a first joining member 81 and a second joining member 82. The first and second wiring patterns 71 and 72 are connected to the respective terminals of a power supply (not shown) outside the light emitting device 200.

As shown in FIG. 5, the first wiring pattern 71 is connected to the first lead 10 via the first joining member 81. Specifically, the first joining member 81 is connected to the top surface of the first wiring pattern 71 and the rear surface 12 of the first lead 10. The second wiring pattern 72 is connected to the second lead 20 via the second joining member 82. Specifically, the second joining member 82 is connected to the top surface of the second wiring pattern 72 and the rear surface 22 of the second lead 20. The first and second joining members 81 and 82 are, for example, solders.

FIG. 6 is an enlarged sectional view illustrating the neighboring portions of the concave portion 520 formed in the light emitting unit 100. As shown in FIG. 6, in a state where the light emitting unit 100 is assembled into the light emitting device 200, the first and second joining members 81 and 82 enter the concave portion 520.

As shown in FIG. 6, a part of the first joining member 81 entering the concave portion 520 contacts the exposed portion 131b of the first side 131. In addition, a part of the second joining member 82 entering the concave portion 520 contacts the exposed portion 231b of the second side 231. These parts are formed when the light emitting unit 100 is mounted on the mounting substrate 70. Specifically, when the first rear surface 12 and the first wiring pattern 71 are soldered, a portion of the solder enters the concave portion 520 along the first rear surface 12 and the exposed portion 131b of the first side 131. Similarly, when the second rear surface 22 and the second wiring pattern 72 are soldered, a portion of the solder enters the concave portion 520 along the second rear surface 22 and the exposed portion 231b of the second side 231. When the solder that is in contact with the exposed portions 131b and 231b is cured, the first and second joining members 81 and 82 are formed as shown in FIG. 6.

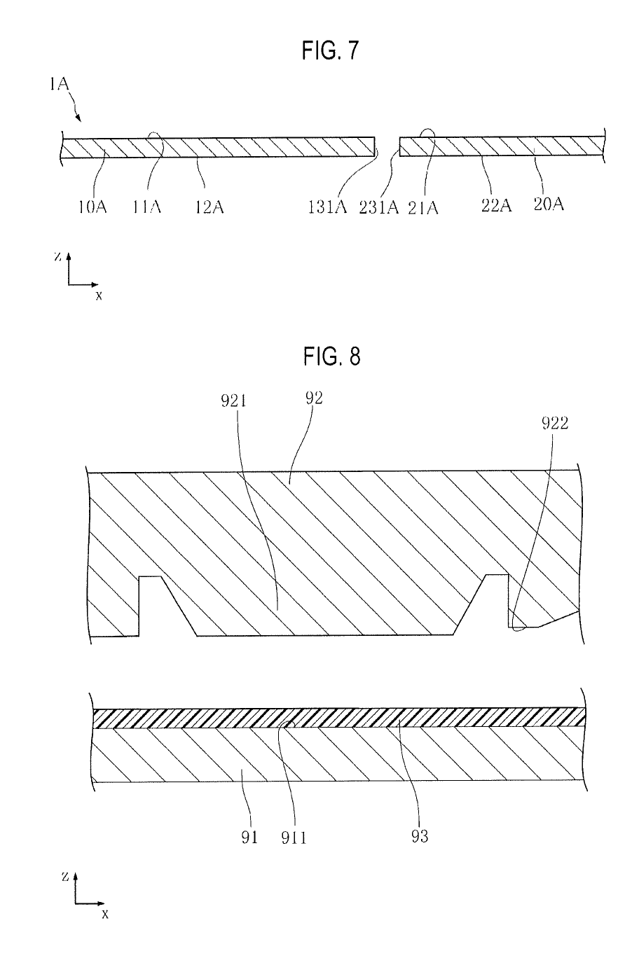

Subsequently, a method of manufacturing the light emitting unit 100 will be described with reference to FIGS. 7 to 14.

FIG. 7 shows an example of a lead frame used to manufacture the light emitting unit 100. A lead frame 1A shown in FIG. 7 includes a first lead 10A and a second lead 20A which are separated from each other. The lead frame 1A is formed, for example by punching or cutting a copper plate of a thickness of about 0.25 mm. The first lead 10A has a principal surface 11A and a rear surface 12A which face opposite each other in the z direction. In addition, the first lead 10A has a first side 131A connecting the principal surface 11A and the rear surface 12A and facing in the right side of FIG. 7. The second lead 20A has a principal surface 21A and a rear surface 22A which face opposite each other in the z direction. In addition, the second lead 20A has a second side 231A connecting the principal surface 21A and the rear surface 22A and facing in the left side of FIG. 7. The second side 231A is a surface facing the first side 131A. A distance between the first side 131A and the second side 231A is, for example, 0.25 mm.

A process of manufacturing the lead frame 1A shown in FIG. 7 is performed in manufacturing the light emitting unit 100. This process includes a step of forming the first lead 10A and a step of forming the second lead 20A. After manufacturing the lead frame 1A, a process of covering the lead frame 1A with first resin material is performed. The process of covering the lead frame 1A with the first resin material corresponds to a process of covering the first lead 10 and the second lead 20 with the first resin material in the above-described embodiment.

FIG. 8 shows a pair of upper and lower molds and resin film, which are used to cover the lead frame 1A with the first resin material. The pair of upper and lower molds includes a lower mold 91 having a bottom surface 911 and an upper mold 92 having a convex portion 921 projecting toward the bottom surface 911. The upper mold 92 is formed with an inlet 922 through which resin material, which will be further described later, is directed to flow into the upper mold 92 when the upper mold 92 is combined with the lower mold 91. A resin film 93 has a form of a film which has a predetermined thickness and is made of, for example, resin having higher stress-deformation than the resin of the first resin molding body 5. Specifically, the resin film 93 may be a polyethylene terephthalate (PET) film and has a thickness of about 0.2 to 0.5 mm. Alternatively, without being limited to the PET film, the resin film 93 may be a film made of, for example, one of polyvinyl chloride, polycarbonate, polypropylene and polyethylene.

In the process of covering the lead frame 1A with the first resin material, a step of interposing the resin film 93 between the pair of upper and lower molds 91 and 92 is first performed. In this step, the resin film 93 is disposed on the bottom surface 911 of the lower mold 91. FIG. 8 shows a state where the resin film 93 is disposed on the bottom surface 911 of the lower mold 91.

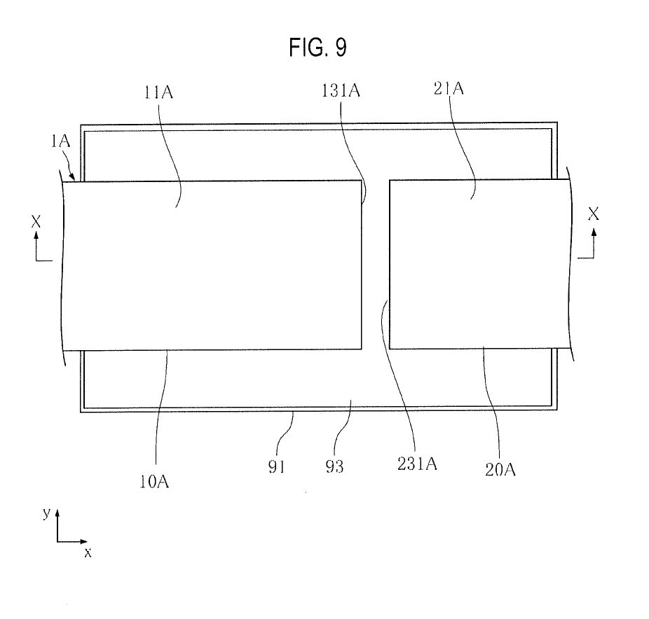

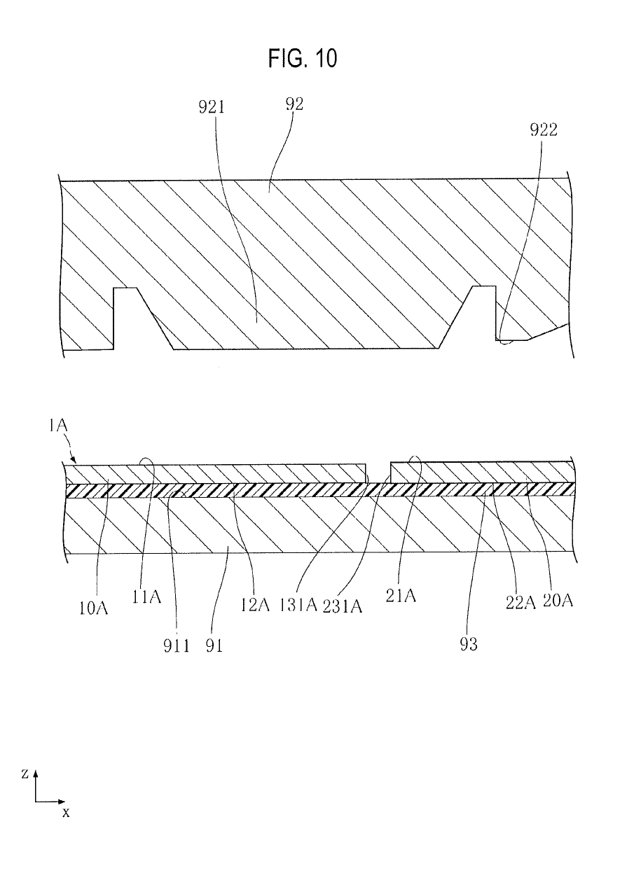

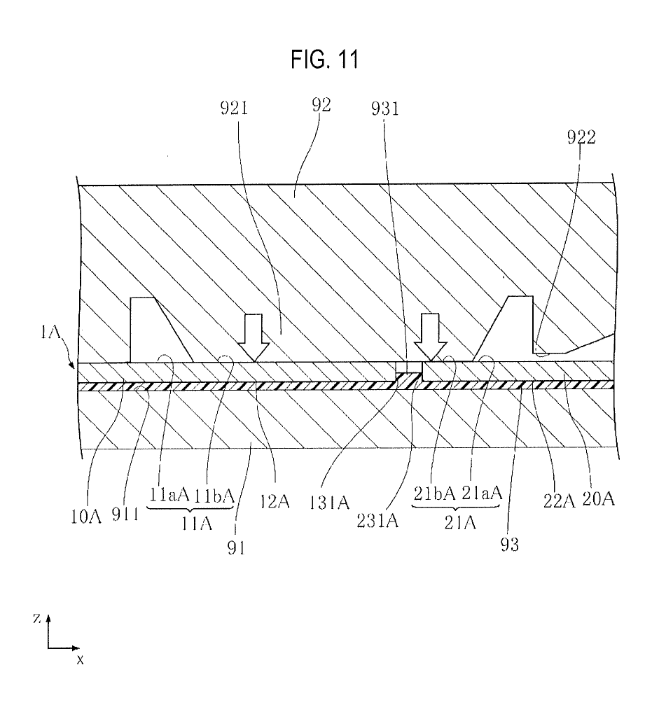

Subsequently, a process of interposing the first lead 10 and the second lead 20 between the pair of upper and lower molds 91 and 92 is performed. This process includes a step of disposing the lead frame 1A on the lower mold 91, as shown in FIGS. 9 and 10, and a step of sandwiching the lead frame 1A between the upper mold 92 and the lower mold 91, as shown in FIG. 11.

As shown in FIG. 10, in the step of disposing the lead frame 1A on the lower mold 91, the first rear surface 12A and the second rear side 22A contact the resin film 93 disposed on the bottom surface 911 of the lower mold 91.

After disposing the lead frame 1A on the lower mold 91, the upper mold 92 is descended toward the lower mold 91. As the upper mold 92 is being lowered, the convex portion 921 contacts the first principal surface 11A and the second principal surface 21A. In this embodiment, even after the convex portion 921 is in contact with the first principal surface 11A and the second principal surface 21A, the upper mold 92 is further descended. Thus, as shown in FIG. 11, the area in contact with the rear surface 12A or the rear surface 22A of the resin film 93 is pressured to shrink in the z direction. On the other hand, since a portion of the resin film 93 overlapping with an area between the side 131A and the side 231A will not be subjected to pressure, this portion is raised in response to deformation of the surrounding, without shrinkage. This allows a portion (or a raised portion 931) of the resin film 93 to enter between the side 131A and the side 231A.

In this step, as shown in FIG. 11, a non-contact portion 11aA is produced in the first principal surface 11A that is not in contact with the upper mold 92 and a close-contact portion 11bA is produced in the first principal surface 11A that is in close contact with the convex portion 921. Similarly, a non-contact portion 21aA is produced in the second principal surface 21A that is not in contact with the upper mold 92 and a close-contact portion 21bA is produced in the second principal surface 21A that is in close contact with the convex portion 921.

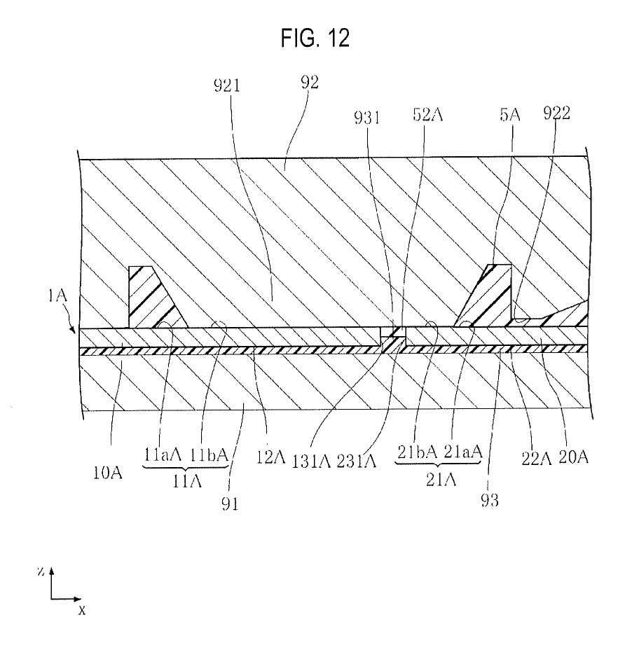

Subsequently, a process of pouring first resin material 5A between the upper mold 91 and the lower mold 92 on which the resin film 93, the first lead 10A and the second lead 20A are disposed is performed. FIG. 12 shows a state after this pouring process. This process is performed by, for example, a transfer mold method. The first resin material 5A is a thermosetting resin forming the above-mentioned first resin molding body 5. The first resin material 5A is introduced between the lower mold 91 and the upper mold 92 from the inlet 922 formed in the upper mold 92.

In this process, the non-contact portion 11aA of the first principal surface 11A and the non-contact portion 21aA of the second principal surface 21A are covered by the first resin material 5A. After the first resin material 5A is cured, the non-contact portion 11aA of the first principal surface 11A becomes the covered portion 11a of the first principal surface 11 and the close-contact portion 11bA becomes the exposed portion 11b. Similarly, after the first resin material 5A is cured, the non-contact portion 21aA of the second principal surface 21A becomes the covered portion 21a of the second principal surface 21 and the close-contact portion 21bA becomes the exposed portion 21b.

As shown in FIG. 12, the first resin material 5A also enters a space sandwiched between the first side 131A and the second side 231A to form the raised portion 931. The raised portion 931 lies in a region near the first rear surface 12A (a lower region in the figure) in the space sandwiched between the first side 131A and the second side 231A. In other words, the first resin material 5A enters only a region near the first principal surface 11A (a lower region in FIG. 12) in the space sandwiched between the first side 131A and the second side 231A. Accordingly, at least a portion of the first side 131A is exposed from the first resin material 5A. A portion of the first resin material 5A lying between the first side 131A and the second side 231A is hereinafter referred to as a band-shaped portion 52A which becomes the band-shaped portion 52 in a later-described process.

Subsequently, a process of curing the first resin material 5A is performed. After curing the first resin material 5A, a process of removing the pair of upper and lower molds 91 and 92 and cutting out an unnecessary portion is performed. Thus, the process of covering the first and second leads 10A and 20A with the first resin material 5A is completed. The first lead 10A with the unnecessary portion removed therefrom becomes the first lead 10. Various parts of the first lead 10A become the corresponding parts of the first lead 10. The second lead 20A with the unnecessary portion removed therefrom becomes the second lead 20. Various parts of the second lead 20A become the corresponding parts of the second lead 20. The first resin material 5A with the unnecessary portion removed therefrom after the curing process becomes the first resin molding body 5 having the window portion 51 corresponding to the convex portion 921.

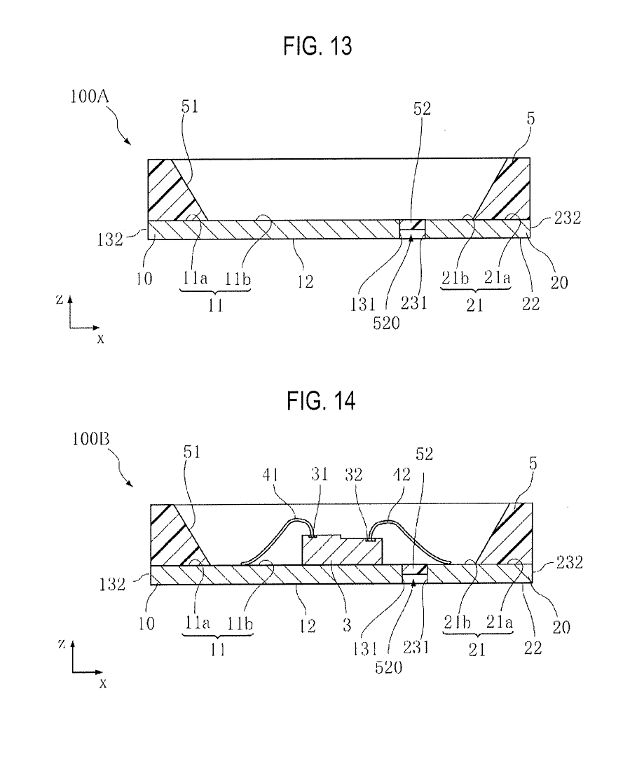

FIG. 13 shows an intermediate 100A resulting from the process of covering the first and second leads 10 and 20 with the first resin material 5A.

The intermediate 100A shown in FIG. 13 includes the first lead 10, the second lead 20 and the first resin molding body 5 in the above-described light emitting unit 100. The concave portion 520 is formed in the intermediate 100A.

After the intermediate 100A is formed, a process of installing the light emitting element 3 and the zener diode 33 and then a process of installing the first wire 41, the second wire 42 and the third wire 43 are performed. An intermediate 100B shown in FIG. 14 can be obtained through these processes.

After the intermediate 100B is formed, the light emitting unit 100 shown in FIGS. 1 to 4 can be completed by performing a process of disposing a second resin material on the window portion 51 and curing the second resin material. The second resin material becomes the second resin molding body 6 after being cured.

Subsequently, an operation of the light emitting unit 100 and a method of manufacturing the same will be described.

In the light emitting unit 100 of this embodiment, the concave portion 520 is formed between the first lead 10 and the second lead 20. The concave portion 520 exhibits the following effect when the light emitting unit 100 is assembled into the light emitting device 200.

As shown in FIGS. 5 and 6, in the light emitting device 200, the first and second joining members 81 and 82 are placed in the concave portion 520. Therefore, the first joining member 81 is in contact with the first side 131 and the second joining member 82 is in contact with the second side 231. With this configuration, a contact area of the first lead 10 with the first joining member 81 and a joining strength therebetween increases, as compared to when no concave portion 520 is disposed. Similarly, a contact area of the second lead 20 with the second joining member 82 and a joining strength therebetween also increases. Accordingly, the light emitting unit 100 can be more firmly connected by the first and second wiring patterns 71 and 72 mounted on the mounting substrate 70 of the light emitting device 200.

In addition, the configuration of the first and second joining members 81 and 82 in the concave portion 520 provides an effect of preventing the first and second joining members 81 and 82 from contacting with each other. The first and second joining members 81 and 82 are produced when the solder used to mount the light emitting unit 100 on the mounting substrate 70 is cured. If the amount of the solder used to mount the light emitting unit 100 on the mounting substrate 70 is excessive, the solder may be spread to an unintended region. If no concave portion 520 is formed, the solder may be spread into a defined region sandwiched between the first and second rear surfaces 12 and 22 and the mounting substrate 70, which may result in contact of the first joining member 81 with the second joining member 82. When the concave portion 520 is formed, the solder permeates into the concave portion 520 along the first lead 10 or the second lead 20. This makes it easy to prevent the first and second joining members 81 and 82 from contacting with each other.

In addition, in this embodiment, the thickness of the band-shaped portion 52 sandwiched between the first lead 10 and the second lead 20 is set to be smaller by an amount corresponding to the concave portion 520 than those of the first and second leads 10 and 20. Since the first and second leads 10 and 20 are made of copper and the first resin molding body 5 is made of resin, it is assumed that a thermal stress is applied to the band-shaped portion 52. The thermal stress applied to the band shaped portion 52 may be mitigated by decreasing the thickness of the band-shaped portion 52.

In the above-described manufacturing method, the resin film 93 is disposed on the lower mold 91 and a portion of the resin film 93 enters between the first lead 10 and the second lead 20. A portion that the resin film 93 enters between the first lead 10 and the second lead 20 becomes the concave portion 520. The process of disposing the resin film 93 can be easily performed and the insertion of the first and second leads 10 and 20 into the upper and lower molds 91 and 92 can be performed by the inherent function of the pair of upper and lower molds 91 and 92.

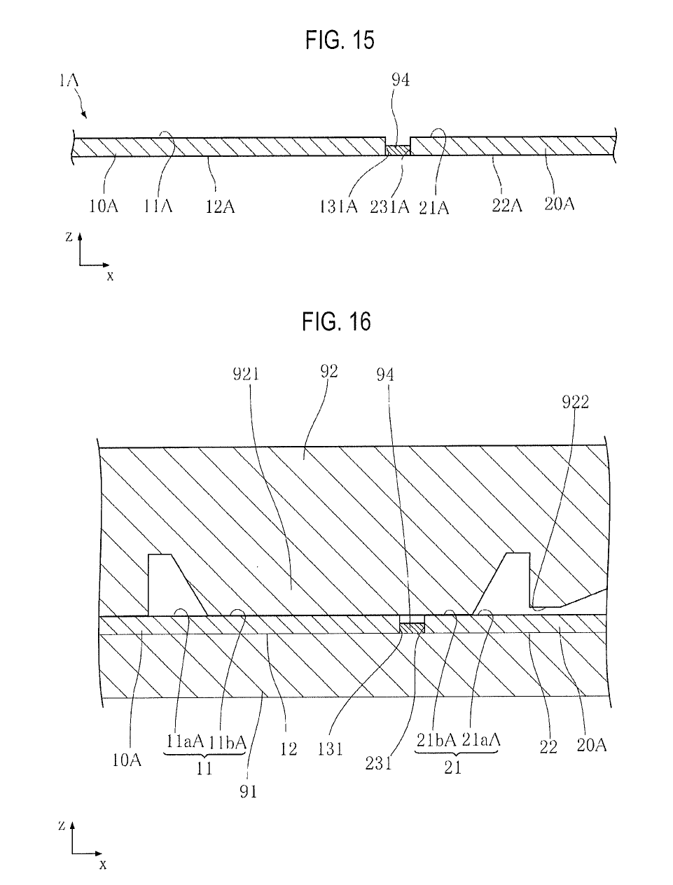

Although the concave portion 520 is formed by inserting the resin film 93 between the pair of upper and lower molds 91 and 92 in the above-described manufacturing method, the concave portion 520 may be formed using a different manufacturing method. Another example of the manufacturing the light emitting unit 100 will be now described with reference to FIGS. 15 to 18. Throughout the following description and FIGS. 15 to 18, the same or similar elements as above are denoted by the same reference numerals as above and explanation of which will not be repeated where appropriate.

In manufacturing the light emitting unit 100, a process of forming the lead frame 1A shown in FIG. 7 is performed. Thereafter, a process of interposing paraffin 94 between the first side 131A and the second side 231A is performed as shown in FIG. 15. As shown in FIG. 15, the paraffin 94 covers a portion of the first side 131A near the first rear surface 12A (in the lower side of FIG. 15). A portion of the first side 131A near the first principal surface 11A (in the upper side of FIG. 15) is exposed from the paraffin 94. Similarly, the paraffin 94 covers a portion of the second side 231A near the second rear surface 22A (in the lower side of FIG. 15). A portion of the second side 231A near the second principal surface 21A (in the upper side of FIG. 15) is exposed from the paraffin 94.

After performing the process of interposing paraffin 94 between the first side 131A and the second side 231A, a process of disposing the first and second leads 10A and 20A between the pair of upper and lower molds 91 and 92 is performed, which is substantially the same as that in the above-described manufacturing method with respect to FIGS. 9 and 10. Although the resin film 93 is disposed on the lower mold 91 in the FIGS. 9 and 10, there is no need to provide the resin film 93 in the manufacturing method using the paraffin 94.

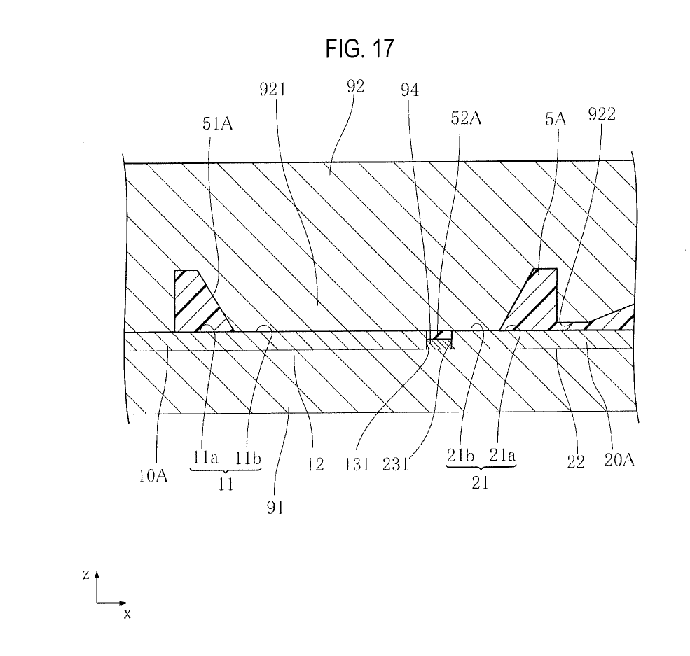

Subsequently, as shown in FIG. 16, a process of lowering the upper mold 92 to approach the lower mold 91 until the convex portion 921 contacts with the first and second principal surfaces 11A and 21A is performed. Thereafter, a process of pouring the first resin material 5A between the upper mold 92 and the lower mold 91 is performed. FIG. 17 shows a state after the first resin material 5A is poured between the upper mold 92 and the lower mold 91. As shown in FIG. 17, the first resin material 5A does not enter a portion where the paraffin 94 is disposed between the first side 131A and the second side 231A. Accordingly, at least a portion of the first side 131A is exposed from the first resin material 5A. In addition, at least a portion of the second side 231A is exposed from the first resin material 5A. On the other hand, as shown in FIG. 17, the first resin material 5A enters an upper region between the first side 131A and the second side 231A in which the band-shaped portion 52A is formed.

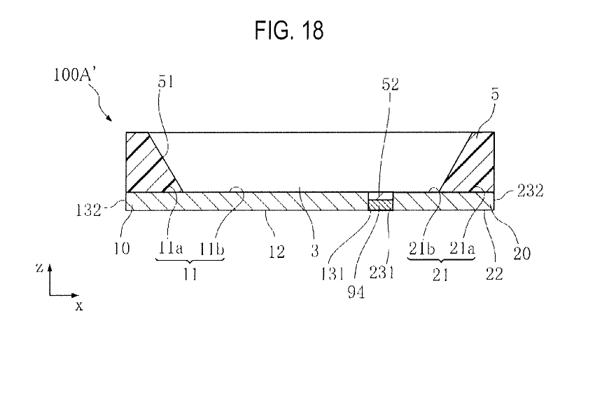

Subsequently, a process of curing the first resin material 5A is performed. After the first resin material 5A is cured, a process of removing the pair of upper and lower molds 91 and 92 and cutting out an unnecessary portion is performed. Thus, the process of covering the first and second leads 10A and 20A with the first resin material 5A is completed. The first lead 10A with the unnecessary portion removed therefrom becomes the first lead 10. Various parts of the first lead 10A become the corresponding parts of the first lead 10. The second lead 20A with the unnecessary portion removed therefrom becomes the second lead 20. Various parts of the second lead 20A become the corresponding parts of the second lead 20. The first resin material 5A with the unnecessary portion removed therefrom after the curing becomes the first resin molding body 5 having the window portion 51 corresponding to the convex portion 921. FIG. 18 shows an intermediate 100A′ resulting from the process of covering the first and second leads 10 and 20 with the first resin material 5A. As shown in FIG. 18, the paraffin 94 remains in the intermediate 100A′.

After performing the process of covering the first and second leads 10 and 20 with the first resin material 5A, a process of heating the paraffin 94 is performed. Specifically, this process is performed by subjecting the intermediate 100A′ to a heating treatment. The heating treatment allows the paraffin 94 to be sublimated and makes it possible to obtain the same as the intermediate 100A shown in FIG. 13.

The light emitting unit, the light emitting device and the method of manufacturing the light emitting unit of the present disclosure are not limited to the above-described embodiments. The detailed configuration of the light emitting unit and the light emitting device of the present disclosure may be changed in design in different ways. Details of the light emitting unit manufacturing method may be also changed.

Although the above-described light emitting unit manufacturing method uses the transfer mold method, the present disclosure is not limited thereto. For example, the first resin molding body 5 may be formed by injection molding, even in which case the resin film 93 or the paraffin 94 can be used to easily form the concave portion 520.

While certain embodiments have been described, these embodiments have been presented by way of example only, and are not intended to limit the scope of the embodiments of the disclosure. Indeed, the novel units, devices and methods described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A light emitting unit comprising:
a light emitting element;
a first lead having a first principal surface on which the light emitting element is disposed, a first rear surface configured to face opposite the first principal surface, and a first side configured to connect the first principal surface and the first rear surface;
a second lead having a second side configured to face the first side; and
a first resin molding body configured to hold the first lead and the second lead,
wherein the first resin molding body covers the first principal surface to expose a region of the first principal surface where the light emitting element is disposed, and
wherein at least a portion of the first side is exposed from the first resin molding body.

2. The light emitting unit of claim 1, wherein the second lead has a second principal surface configured to face in the same direction as the first principal surface and a second rear surface configured to face in the same direction as the first rear surface,
wherein the first resin molding body covers the second principal surface to expose a portion of the second principal surface, and
wherein at least a portion of the second side is exposed from the first resin molding body.

3. The light emitting unit of claim 2, wherein the first rear surface and the second rear surface are exposed from the first resin molding body.

4. The light emitting unit of claim 3, wherein the first resin molding body has a band-shaped portion configured to contact the first side and the second side.

5. The light emitting unit of claim 4, further comprising a concave portion sandwiched between the first side and the second side,
wherein the band-shaped portion faces the concave portion.

6. The light emitting unit of claim 5, further comprising a second resin molding body configured to cover the light emitting element,
wherein the first resin molding body has a window portion formed to accommodate the second resin molding body.

7. The light emitting unit of claim 6, wherein the second resin molding body contacts the first principal surface and the second principal surface, and
wherein the band-shaped portion contacts the second resin molding body.

8. A light emitting device comprising:
the light emitting unit of claim 1;
a first wiring pattern connected to the first lead; and
a first joining member configured to connect the first wiring pattern and the first rear surface.

9. The light emitting device of claim 8, wherein the first joining member contacts the first side.

10. A light emitting device comprising:
the light emitting unit of claim 2;
a first wiring pattern connected to the first lead;
a first joining member configured to connect the first wiring pattern and the first rear surface;
a second wiring pattern connected to the second lead; and
a second joining member configured to connect the second wiring pattern and the second rear surface.

11. The light emitting device of claim 10, wherein the second joining member contacts the second side.

12. A method of manufacturing a light emitting unit, comprising:
forming a first lead having a first principal surface, a first rear surface configured to face opposite the first principal surface, and a first side configured to connect the first principal surface and the first rear surface;
forming a second lead having a second side configured to face the first side; and
covering the first lead and the second lead with a first resin material,
wherein covering the first lead and the second lead with the first resin material includes exposing at least a portion of the first side from the first resin material.

13. The method of claim 12, wherein covering the first lead and the second lead with the first resin material includes:
interposing a resin film between a pair of upper and lower molds;
interposing the first lead and the second lead between the pair of upper and lower molds such that the first rear surface contacts the resin film; and
pouring the first resin material between the pair of upper and lower molds on which the resin film, the first lead and the second lead are disposed.

14. The method of claim 13, wherein the second lead has a second rear surface configured to face in the same direction as the first rear surface, and
wherein interposing the first lead and the second lead between the pair of upper and lower molds includes contacting the second rear surface with the resin film.

15. The method of claim 13, wherein interposing the first lead and the second lead between the pair of upper and lower molds includes putting a portion of the resin film between the first side and the second side.

16. The method of claim 13, wherein the pair of upper and lower molds includes a lower mold having a flat bottom surface and an upper mold having a convex portion configured to project toward the bottom surface, and
wherein the resin film is disposed on the bottom surface.

17. The method of claim 16, further comprising contacting the convex portion with the first principal surface.

18. The method of claim 17, wherein the second lead has a second principal surface configured to face in the same direction as the first principal surface, and
wherein contacting the convex portion with the first principal surface includes contacting the convex portion with the second principal surface.

19. The method of claim 17, wherein covering the first lead and the second lead with the first resin material includes forming a first resin molding body having a window portion corresponding to the convex portion.

20. The method of claim 19, further comprising:
disposing a light emitting element in the window portion; and
covering the light emitting element with a second resin material,
wherein covering the light emitting element with the second resin material includes forming a second resin molding body covering the light emitting element.

21. The method of claim 12, wherein covering the first lead and the second lead with the first resin material includes:
interposing paraffin between the first side and the second side; and
heating the paraffin after covering the first lead and the second lead with the first resin material.

22. The method of claim 21, wherein interposing the paraffin includes covering a portion of the first side near the first rear surface with the paraffin and exposing a portion of the first side near the first principal surface from the paraffin.

23. The method of claim 22, wherein the second lead has a second principal surface configured to face in the same direction as the first principal surface and a second rear surface configured to face in the same direction as the first rear surface, and
wherein interposing the paraffin includes covering a portion of the second side near the second rear surface with the paraffin and exposing a portion of the second side near the second principal surface from the paraffin.
